(19) United States
(12) Patent Application Publication
(10) Pub. No.: US 2005/0062481 A1
(43) Pub. Date: Mar. 24, 2005

(54) Wayside LED signal for railroad and transit applications

(76) Inventors: Thomas Vaughn, Hesperia, CA (US); Jim E. Walker, San Bernadino, CA (US); H. James Wilson, Nuevo, CA (US)

Correspondence Address: Cook, Alex, McFarron, Manzo, Cummings & Mehler, Suite 2850, 200 West Adams, Chicago, IL, 60606, US

(21) Appl. No.: 10/664,656

(22) Filed: Sep. 19, 2003

(51) Int. Cl. G01R 31/00

(52) U.S. Cl. 324/500

(57) ABSTRACT

A LED signal lamp that monitors, controls and tests the operational status of a plurality of LEDs. A separate current source is provided for each LED and resistors are in series between the current sources and LEDs. Analog-to-digital converters monitor the voltages at the resistors and LEDs and convert the voltages to digital form for a data processor. The data processor determines the junction temperature of each LED, controls the amount of current supplied to each LED and tests the operational status of each LED by matching its characteristics to a known diode curve. A pulse-width modulator provides further control of the amount of power supplied to the current sources. The data processor further controls a vital disconnect and a vital load. An energy storage/limiter circuit stores energy for the data processor during the absence of normal power input. Related methods of monitoring, controlling and testing such an LED system are also disclosed.

### FIELD OF THE INVENTION

This invention relates generally to apparatus and methods for using light emitting diodes (LEDs) in signal applications, and more particularly, to apparatus and methods for determining the operational integrity of LEDs in wayside signals for railroad and transit applications.

### BACKGROUND OF THE INVENTION

Wayside signals are located along the right of way on railroad tracks and are used to display the signal aspects to a locomotive or other rail transit vehicle. For example, information on allowable track speeds and track conditions ahead may be displayed, including whether a switch will provide straight through or diverting movement. Historically, these signal aspects have been displayed by using incandescent light bulbs. More recently, LEDs have been used in wayside signals. The benefits of LEDs over incandescent bulbs include improved visibility, higher reliability and lower power consumption.

However, interfacing such LED signals with equipment in the field has raised many major issues. Wayside signals are energized from either vital relay-based systems or from vital processor-based systems. Both types of systems are typically located in an enclosure that is removed from the signal itself and that contains control logic that is available from a variety of manufacturers. These two types of systems have different interface characteristics that vary substantially within the various processor-based systems.

Part of the interfacing issue is what is referred to in the industry as hot and cold filament checking. While these terms originated with incandescent bulbs, the underlying concepts apply equally well to LED signals. Hot filament checking implies that visible light is being emitted when an appropriate input, typically a voltage, is being applied to the signal head. Filament checking is a safety issue, but it can also provide operational advantages.

A “dark” signal is one that is not emitting any light even though the proper input voltage is applied. For incandescent bulbs, a broken filament wire is the likely cause of failure. A dark aspect that is part of a multi-aspect signal has the potential of having the overall aspect misinterpreted by the engineer of railroad equipment. For example, a location with a switch machine typically has two signal aspects governing movement across it. Each aspect can be emitting Red, Yellow or Green light. When the switch is aligned reverse for a diverging move, the top aspect is red and the bottom aspect is yellow. This informs the engineer that he must be traveling slow enough to traverse the reverse switch. However, if the red aspect were “dark”, the engineer would only see the yellow aspect from a distance. This indicates to the engineer that he can operate at a higher speed than is permissible to traverse the switch in the reverse position, which may potentially cause an accident. Railroad rules cover operation for “dark” signals. However, environmental conditions may prevent the engineer from becoming aware that the signal is dark until it is too late to reduce the speed of the locomotive. The Federal Railroad Administration (FRA) has issued a specific rule to cover such safety-critical operations. See, Rule 236.23 (f) of 49 C.F.R. This situation is handled by control logic in the wayside systems that energize the signal. The control logic determines if the signal is “dark” and modifies the displayed aspect to a more restrictive aspect than would normally be seen. In this example, the control logic would change the bottom aspect to red requiring the train to stop at the switch. In many cases, there is an operational advantage as well as a safety advantage to verify that the aspects are being correctly displayed. Frequently, determining that an aspect is not correctly illuminated allows a degraded (less permissive) aspect to be displayed avoiding a stop and proceed, or an absolute stop. For example, if a “green” aspect was not being displayed, it could be downgraded to a yellow aspect allowing continued movement of the train, although at a lower speed.

Cold filament checking is similar, but a check is done when the aspect is not illuminated. This provides advance knowledge of a lamp or LED failure so that the preceding aspect can be downgraded in advance, thus preventing a sudden unexpected downgrade.

With incandescent bulbs, it is generally accepted that no current flow through the bulb is an indication that no visible light is being emitted. There are instances that this is not true, such as when a bulb socket is corroded. Such instances are sufficiently rare that they do not pose a significant safety risk. However, this is not necessarily the case with LED signals. First, LEDs may not necessarily be emitting light if they are drawing current. For example, certain LED technologies have embedded protection diodes as part of the LED. These embedded protection diodes have the potential for shorting and allowing current to flow, which bypasses the light generating portion of the LED.

It has been suggested that the reliability of LEDs is so high that there is no need to check whether any LED is “dark”. There have also been some suggestions that it is effective to simply replace the LED assemblies every few years instead of verifying light output. However, the published or manufacturer's mean time between failure (MTBF) data are based upon averages and neglect manufacturing anomalies, such as solder connections, production anomalies and failures due to the environment, such as power transients due to lightning. Reliance upon MTBF data also means that the safety of using LEDs in wayside signals may need to be reevaluated each time that the LED manufacturing processes and/or technology changes. A second issue of concern is that, unlike incandescent bulbs, LED signals generally have electronic components in the signal head to provide a regulated, constant current supply to the individual LEDs. Failure of these electronic components also has the effect of allowing the signal head to draw current even though no light is being generated. Failure of any LED also creates a higher risk for overall reliability, including the failure mode in which all of the LEDs may go dark simultaneously.

Wayside mounted relay-based and processor-based systems perform these hot and cold filament tests in substantially different ways. Relay-based systems typically measure one value of continuous current when the aspect is illuminated (i.e., a hot filament test), and a second continuous value when the aspect is not illuminated (or when the current is low enough that no light is emitted by the incandescent bulb, i.e., a cold filament test). The first current value requires that LED replacement signals draw at least the minimum current value drawn by an incandescent bulb when illuminated. Likewise, replacement LEDs in a relay-based system must draw a minimum value of current when not illuminated, while making sure that this minimum current does not allow any light to be generated from the LEDs.

Some processor-based systems operate similarly to the relay-based systems, but many others use a brief output pulse of full power to the signal head to verify that current is being drawn. This output pulse is usually only a few milliseconds, and occurs approximately once per second. A pulse of this width is not long enough for an incandescent bulb to respond to, but can easily turn on an LED to full brightness for a few milliseconds. This brief flash is generally not of sufficient duration to be interpreted as a signal aspect under normal viewing conditions. However, dense fog, snowstorms or rainstorms could easily allow such a flash to be erroneously interpreted as a continuous aspect.

A wayside signal is a safety-critical device since any failure may directly result in an accident, causing property damage or loss of life. Such systems are therefore designed in accordance with fail-safe or vital principles. Industry accepted practices define design and analysis techniques for determining that a circuit or system is vital (fail-safe), such as: American Railway Engineering an Maintenance of Way Association (AREMA), Manual of Communications and Signals, Manual Part 7.1.5 “Recommended Design Criteria and Functional/Operating Guidelines for an LED Light Unit Used in Wayside Applications” and Manual Part 17.3.1 “Recommended Safety Assurance Program for Electronic/Software Based Products Used in Vital Signal Applications.”

Where the description contained herein refers to vital or fail-safe design, this implies that the design is done in accordance with generally accepted industry standards, including those in the AREMA Manual.

Accordingly, it is a general object of the present invention to provide a new and improved LED signal lamp system that can replace a prior incandescent lamp system.

Another object of the present invention is to provide a LED signal lamp that verifies that the LEDs are functional, such as with comparisons to a known diode voltage-current characteristic.

Yet another object of the present invention is to provide a LED signal lamp with a separate current source for each LED and means of monitoring the amount of current supplied by the current sources.

A further object of the present invention is to provide a LED signal lamp in which the amount of current supplied to the LEDs is controlled by pulse-width modulation techniques.

A still further object of the present invention is to provide a LED signal lamp with means to determine the junction temperature of the LEDs and to modify the current supplied to the LEDs in accordance with the junction temperature determinations.

Another object of the present invention is to provide methods for operating, controlling and testing LEDs in a signaling system, including determining the operational status thereof.

### BRIEF SUMMARY OF THE INVENTION

This invention is directed to apparatus and methods for using LEDs in signal applications. Current to the LEDs is controlled by various techniques. The operational status of the LEDs is also monitored by various techniques.

The circuitry for the LED signal includes a plurality of LEDs and a plurality of current sources for supplying current to the LEDs, with a separate current source for each LED. A plurality of resistors is interposed between the current sources and the LEDs, and in series therewith. Analog-to-digital converters monitor the voltage potentials at each of the plurality of resistors and at each of the plurality of LEDs and provide digital representations of the voltage potentials to a data processor.

The data processor uses the voltage information from the resistors and LEDs to determine the amount of current supplied to each LED and to determine the junction temperature of the LEDs. The data processor has a data bus to communicate with the current sources and other portions of the system. The data processor determines the junction temperature of the LEDs by determining the difference in potential between the current measurement from the analog-to-digital converter and a known reference potential at a predetermined temperature. Using a known temperature coefficient for the LEDs, the current junction temperature is determined. The data processor also determines the operational integrity of each LED by rapidly sequencing each current source through different current levels, and comparing the resultant potentials to a known diode voltage-current characteristic. The data processor also rapidly conducts these tests by sequentially controlling the plurality of current sources such that the tests do not appreciably change or degrade the human perception of the illumination characteristics of the LEDs during the tests. The data processor also vitally disconnects the load from the source to emulate an open circuit.

An energy storage/limiter circuit stores energy for operation of the data processor during the absence of normal power input. In one possible implementation, a capacitor may be used to store sufficient energy to operate the microprocessor. In a second possible implementation, a battery may be used as the energy storage device. Energy stored is sufficient to operate the microprocessor and the LEDs cannot be illuminated unless the proper input is present. A vital load circuit is controlled by the data processor to emulate the load drawn by an incandescent lamp. A vital disconnect, also operating under control of the data processor, can disconnect the system to emulate an open circuit similar to what would be seen if the filament of an incandescent bulb were to open. A pulse-width modulator, operating under control from the data processor, may provide further control of the amount of power supplied to the current sources.

Related methods that are used to monitor, control and test such an LED signal lamp system are also disclosed.

### BRIEF DESCRIPTION OF THE DRAWINGS

The features of the present invention which are believed to be novel are set forth with particularity in the appended claims. The invention, together with the further objects and advantages thereof, may best be understood by reference to the following description taken in conjunction with the accompanying drawings, in the figures in which like reference numerals identify like elements, and in which:

FIG. 1A is a schematic representation of a light emitting diode (LED) of the AlInGaP type;

FIG. 1B is a schematic representation of an LED of the InGaN type with back-to-back Zener diode protection;

FIG. 2 is a typical voltage versus current graph for a diode, including LEDs;

FIG. 3 is an electrical schematic of the system for monitoring and testing a plurality of LEDs in a railroad or transit application;

FIG. 4 is a flow chart of representative tests conducted by a microprocessor in the electrical schematic of FIG. 3; and

FIG. 5 is a flow chart of representative steps for monitoring and testing the LEDs in a wayside signal in accordance with the present invention.

### DESCRIPTION OF THE PREFERRED EMBODIMENT

In order to fully understand the present invention, an appreciation of LED technology and the structure and operation of the different types of LEDs is needed. An LED is a semiconductor device that emits light when current flows through it in the forward direction. The light emission results when electrons are separated from atoms in the crystalline material and recombine with the resulting holes. The electrons then release energy in the form of photons. The material composition of LEDs is tailored to create energy levels that correspond to particular regions in the visible light spectrum.

For example, an AlInGaP material produces light in the red, yellow and orange regions of the spectrum, i.e., wavelengths in the range of 600 to 700 nm. An InGaN material produces light in the blue, green and cyan regions of the spectrum, i.e., wavelengths in the range of 400 to 550 nm. The dominant wavelength of the light emitted by a particular diode can vary to some extent, and wavelength depends upon variations in the manufacturing process, applied forward current and junction temperature. Process variations are dealt with by the manufacturer binning or sorting the LEDs according to dominant wavelength. The forward current and junction temperature variables must be controlled by the power supply and by thermal management techniques.

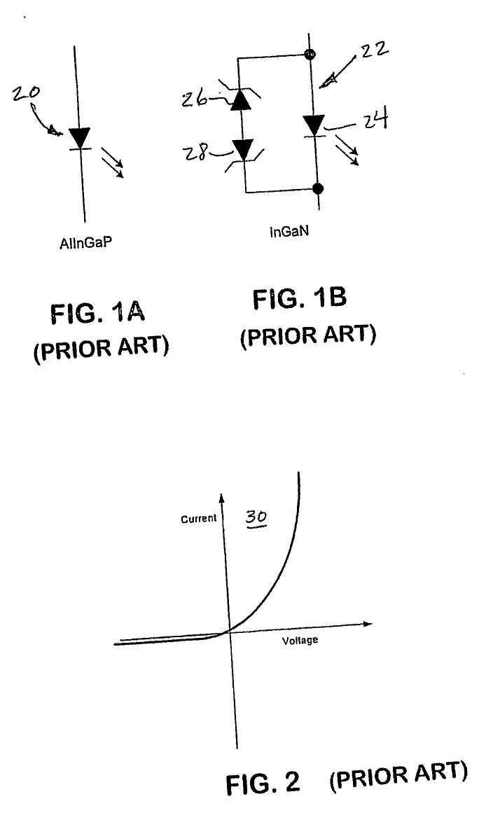

The physical structure of the LED depends upon the material used for the die. The structure of the AlInGaP LED, generally designated 20 in FIG. 1A, is the simplest. It consists of a die mounted on a GaP substrate. The substrate is in turn soldered to a metallization layer. Wire bonds are soldered or bonded to the metallization layer and to the top of the die.

The structure of the InGaN device, generally designated 22 in FIG. 1B, is more complicated. Because the InGaN material is inherently more susceptible to electrostatic discharge (ESD) than AlInGaP material, its structure includes back-to-back Zener diodes 26 and 28 in parallel with the LED 24 to prevent damage to the junction of the LED from static discharge. In order to obtain high light extraction efficiency, a flip-chip arrangement is used. The equivalent circuits of the two structures are shown in FIGS. 1A and 1B.

In order to use LEDs as a replacement for incandescent light bulbs, it is important to understand the failure modes of LEDs. The possible failure modes of the two types of structures discussed above can be categorized as follows:
1. Failures of the light emitting diode die.
2. Failures of connections to the die.
3. For InGaN devices only, failure of the back-to-back Zener diodes on the submount.

The following table considers these failures and their effect on the operation of typical LEDs, such as LEDs 20 and 22. Most failures can be separately analyzed. However, the Zener diodes 26 and 28 on the InGaN devices 22 are intended to handle high-voltage electrostatic discharges. If the energy level of these discharges is high enough, both Zener diodes 26 and 28 could fail simultaneously from a single discharge event. These combination failures are also considered in the table. It is also possible that both Zener diodes could fail and enough energy remains to damage the light emitting diode die immediately afterward. This type of failure is also considered in the table below, as well as numerous other failure modes.

| | | Predicted Effect(s) of |
|---|---|---|
| Component | Failure Mode(s) | Failure |
| Bond wire | Open | Device draws no current. |
| to die or | | No light emitted. |
| substrate | | |
| Solder | Open | Device draws no current. |
| connection | | No light emitted. |
| to die or | | |
| bond wire | | |
| Solder | High resistance | Device draws reduced |
| connection | | current. Light output |
| to die or | | reduced. |
| bond wire | | |
| Die | Junction fused | Device has V-I curve |
| | | characteristic of a |
| | | resistor. No light |
| | | emitted. |
| Die | Junction | Device has V-I curve |
| | partially fused. | characteristic of a |
| | | resistor in parallel with |
| | | a diode junction. Light |
| | | output reduced, possible |
| | | to zero. |
| (InGaN | Short | Lower Zener diode hogs |
| Only) | | current from LED because |
| Upper Zener | | of its lower forward |
| diode (26 | | voltage drop. Light |
| in FIG. 1B) | | output reduced, possible |
| | | to zero. |
| (InGaN | Open or high | ESD protection is reduced |
| Only) | resistance | or absent. Increased |
| Upper Zener | Zener voltage | likelihood that unit may |
| diode (26 | increases. | be damaged by handling |
| in FIG. 1B) | | prior to installation on |
| | | circuit board, or by |
| | | mishandling of circuit |
| | | board after the device is |
| | | installed. |
| (InGaN | Low resistance | Some current will be |
| Only) | but not a short. | diverted from LED through |
| Upper Zener | Zener voltage | the lower Zener diode. |
| diode (26 | decreases below | Reduced light output. V- |
| in FIG. 1B) | forward voltage | I characteristic of LED |
| | drop of LED. | is skewed by series |
| | | combination of resistance |
| | | and forward diode |
| | | junction in parallel with |
| | | LED junction. |
| (InGaN | Open or high | ESD protection is |
| Only) | resistance. | reduced. Increased |
| Lower Zener | Short. or low | likelihood that unit may |
| diode (28 | resistance | be damaged by handling |
| in FIG. 1B) | Zener voltage | prior to installation on |
| | increases. | circuit board, or by |
| | | mishandling of circuit |
| | | board after the device is |
| | | installed. |
| (InGaN | Zener voltage | No effect. |
| Only) | decreases. | |
| Lower Zener | | |
| diode (28 | | |
| in FIG. 1B) | | |
| (InGaN | Both diodes fail | Some or all current will |
| Only) | simultaneously | be diverted from the LED |
| Upper and | shorted or low | through the failed Zener |
| lower Zener | resistance. | diodes. Reduced light |
| diodes (26 | | output. V-I |
| and 28 in | | characteristic of LED is |
| FIG. 1B) | | skewed by series |
| | | combination of failed |
| | | Zener diodes in parallel |
| | | with LED junction. |
| (InGaN | All other | ESD protection is |
| Only) | combinations of | reduced. Increased |
| Upper and | simultaneous | likelihood that unit may |
| lower Zener | failures of both | be damaged by handling |
| diodes (26 | Zener diodes. | prior to installation on |
| and 28 in | | circuit board, or by |
| FIG. 1B) | | mishandling of circuit |
| | | board after the device is |
| | | installed. |
| (InGaN | Either or both | The open or high |
| Only) | Zener diodes | resistance Zener diodes |
| Upper and | opens or becomes | effectively remove |
| lower Zener | high resistance | themselves from the |
| diodes (26 | and any failure | circuit. The failures of |
| and 28 in | of the LED die or | the bond wires and solder |
| FIG. 1B) | its bond wire(s) | connections then are |
| and LED 24. | and solder | covered by rows 1 through |
| | connections. | 3 above. If the bond |
| | | wires or solder |
| | | connections open or |
| | | become high resistances, |
| | | regardless of damage to |
| | | the die itself, then the |
| | | light output will be |
| | | reduced, possibly to |
| | | zero. If only the |
| | | junction is damaged, then |
| | | the analyses of rows 4 |
| | | and 5 apply. |

It is readily apparent from the various failure modes considered in the above table that only measuring current flow through the LED, or an array of LEDs, is not sufficient to verify that light is being emitted. The present invention uses processor-based technology coupled with various sensors to verify that the LED is performing as a diode. This is done by monitoring the current and voltage at each individual LED. Semiconductor diodes, including LEDs, have a non-linear current vs. voltage characteristic, generally designated 30 in FIG. 2. FIG. 2 generally depicts this non-linear relationship. When positively biased, the current increases rapidly for small increases in voltage.

The present invention makes use of a microprocessor-based controller, current sources that can be controlled by the microprocessor, analog-to-digital converters that are used to read voltage inputs, and other vital circuits that will be described below. These techniques allow various current values to be input to each LED with the corresponding voltage read back into the microprocessor. By selecting currents and voltages that are unique to the type of LEDs being used, the current vs. voltage relationship can be compared to the range acceptable for that type of LED and verification can be made that the LED is operating correctly and that light is being emitted. Because of the very low power consumption of the microprocessors, they can be powered either by relay or processor-based systems.

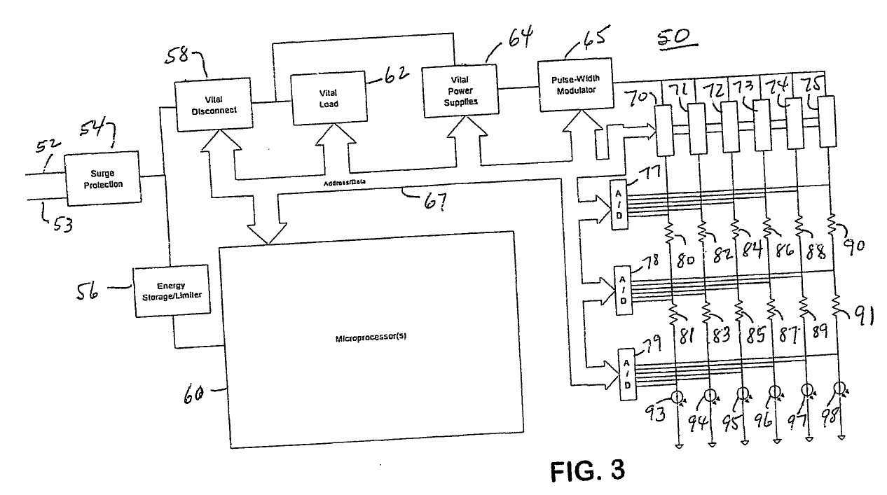

FIG. 3 is an electrical schematic diagram that illustrates the preferred embodiment of the electronic circuitry, generally designated 50, for practicing the present invention. Input operating voltage is received on a pair of lines 52 and 53 at a surge protector 54. Surge protector 54, in turn, supplies power to an energy storage/limiter 56 and to a vital disconnect 58. The energy storage/limiter 56 converts pulsed energy from the processor-based source to a steady energy capable of supplying energy to one or more data processors, such as microprocessors 60. Alternatively, a battery may be used for the energy storage function. Where desired, this allows the microprocessor to operate independently of connection to a power source. In all implementations, this function also vitally limits the current being drawn from either a relay or a processor-based source. This is important since any failure in the energy storage/limiter 56 could cause sufficient current to be drawn to cause the source to erroneously interpret that an LED was emitting light, when in fact, the LEDs were not energized. Vital disconnect 58, in turn, allows power to be transferred to a vital load 62. A vital power supply 64 is enabled by the microprocessor 60 transferring input power to a pulse-width modulator (PWM) 65 when the processor is operating correctly and there are no other failures in the LEDs. PWM 65 supplies power to a plurality of current sources 70-75. Each current source 70-75 supplies current to an LED 93-98 through a pair of resistors 80-91 connected in series. For example, current source 70 supplies current to LED 93 through a pair of resistors 80-81.

Microprocessor 60 receives and sends information via an address/data bus 67. As illustrated in FIG. 3, microprocessor 60 sends and/or receives information from vital disconnect 58, vital load 62, vital power supplies 64, pulse-width modulator 65, current sources 70-75 and A/D converters 77-79.

An analog-to-digital (A/D) converter 77 determines the analog voltage at each of resistors 80, 82, 84, 86, 88 and 90 associated with LEDs 93-98, respectively. A/D converter 77 then converts the analog voltage for the selected resistors to digital form and communicates the digital value to microprocessor 60 over an address/data bus 67, such as by multiplexing the digital values for the measured potential at each resistor. Since the resistive values of resistors 80-91 are fixed and known, microprocessor 60 can determine the amount of current being supplied to each LED 93-98 by the respective current source 70-75. In order to obtain the most accurate determination of current being supplied to each LED 93-98, resistors 80-91 are preferably of low tolerance, such as+one percent, or less. Of course, if any LED has failed and is not conducting current, the potential at the associated resistor will rise. Microprocessor 60 will then be able to determine that the LED is faulty from the digital value of the potential supplied by A/D converter 77.

A/D converter 78 similarly gathers information about the analog voltages present at resistors 81, 83, 85, 87, 89 and 91, and provides the digital equivalent to microprocessor 60 over the bus 67. This will provide comparative data to the microprocessor to cross-check on the data from A/D converter 77. Multiple A/D converters and resistors, or other techniques, are also used to mitigate potential failures that would cause errors in reading the LED currents.

As before, the analog voltages at resistors 81, 83, 85, 87, 89 and 91 will be indicative of the current supplied by each current source 70-75 to the respective LED 93-98. Similarly to A/D converter 77, if any LED has failed and is not conducting current, the voltage at the associated resistor will rise and microprocessor will determine which LED has failed from the digital information supplied by A/D converter 78.

A/D converter 79 directly monitors the analog voltage across each of LEDs 93-98, and supplies the digital equivalents of the analog voltages to microprocessor 60 via bus 67. Microprocessor 60 can determine the junction temperature of each LED by the known forward biased junction potential. For example, if the junction of each LED 93-98 is about 3.0 volts at 20° C., and if the temperature coefficient of the forward biased junction potential is known to be about −2.2 millivolts per ° C., microprocessor 60 can calculate the junction temperature of each LED based upon the current analog voltages measured by A/D converter 79. Microprocessor 60 can then adjust the current supplied by the respective current source 70-75 for optimum operation. For example, microprocessor 60 may change the pulse-width modulation at modulator 65 of the power being supplied to all current sources 70-75, or may independently customize one of the current sources 70-75 to the desired current level. As previously mentioned, the junction temperature is one of the factors that affect the amount of light being emitted by the LEDs.

A/D converter 79 is also used in testing of LEDs 93-98 to see if these LEDs conform to the diode current-voltage characteristic of FIG. 2. That is, converter 79 monitors the forward biased junction potential of each of LEDs 93-98 for various current levels supplied by current sources 70-75, and reports the digital equivalents of the measured potentials to microprocessor 60. As another example, if any LED has failed, the potential at the failed LED will be well above the forward biased potential. A/D converter 79 will convey the measured potential to microprocessor 60, which will then be able to determine which LED is not operational.

The microprocessor 60 may consist of one or more microprocessors, depending on techniques used to achieve system safety. Microprocessor(s) 60 may be any suitable data processor, including microcontrollers or the like. Microprocessor 60 is selected to operate on very low power so that it may continue to operate even when the signal is not being illuminated. As discussed previously, an existing relay-based interface provides a continuous voltage during the off time, although the available current is limited sufficiently so that an incandescent bulb could not be illuminated. For processor-based interfaces, a short pulse (typically one millisecond in duration) is generated approximately every second. This pulse is too short to illuminate an incandescent bulb, but could illuminate a plurality of LEDs if applied directly to them.

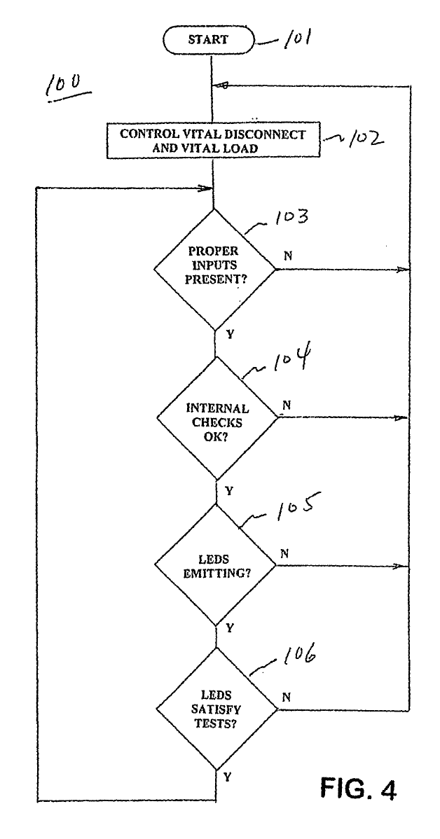

FIG. 4 is a flow chart, generally designated 100, illustrating representative steps that may be employed by microprocessor 60 in controlling the vital disconnect 58 and the vital load 62; block 102 in FIG. 4. The vital disconnect 58 is used to vitally disconnect the LED lighting system, which includes the electronic circuitry 50 in FIG. 3, from the source voltage, thus presenting high impedance to the source. The vital disconnect 58 presents a high impedance to the source when the proper input is not present, as in decision block 103, when the microprocessor is not satisfying its internal safety checks, as in decision block 104, when the microprocessor determines that a sufficient number of the LEDs are not either emitting or capable of emitting light, as in decision block 105, or when microprocessor 60, otherwise determines that a sufficient number of LEDs fail to satisfy other tests such as the criteria for the hot filament or cold filament tests, as in decision block 106.

The vital load 62 is controlled by the microprocessor 60 to sink sufficient current to satisfy the interface hot filament test requirement. This is necessary because the electronic circuitry 50, including LEDs 93-98, does not use sufficient current to satisfy the requirements of existing interfaces.

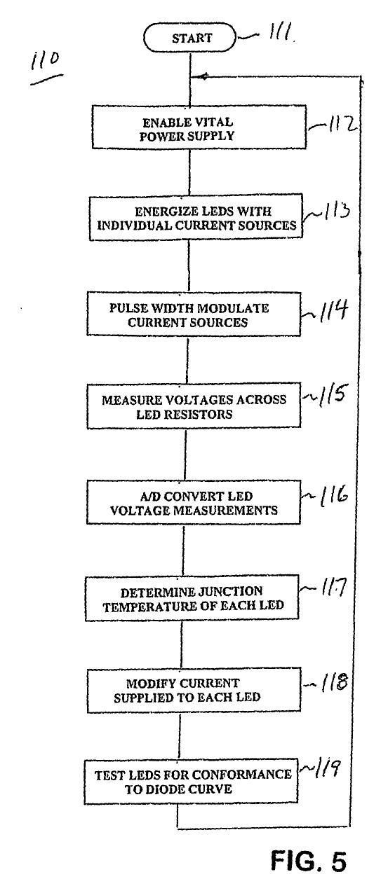

FIG. 5 is a flow diagram, generally designated 110, illustrating representative steps that may be employed by microprocessor 60 in energizing, controlling, monitoring and testing the LEDs 93-98 of FIG. 3. Microprocessor 60 enables the vital power supply 64 to generate energy used for testing and supplying power to LEDs 93-98, as in block 112. The vital power supply 64 is enabled only when the microprocessor 60 has first verified that it (microprocessor 60) is performing properly. If so, microprocessor 60 energizes the LEDs with a plurality of current sources 70-75, as in block 113, with one current source for each LED. Energization of the LEDs may be controlled by pulse-width modulating the current sources 70-75, as in block 114, allowing the proper average current to flow through each individual LED.

The current flowing through each LED 93-98 is determined by measuring the voltage across resistors 80-91 with A/D converters 77-78, as in block 115. These A/D converters convert the measured analog voltages to digital form and multiplex the digital representations of the voltages to microprocessor 60, as in block 116. A/D converter 79 measures the voltage across each LED, converts the analog voltage to digital form and multiplexes the digital representations of the analog voltages to the microprocessor 60. Based upon the voltage across each LED, microprocessor 60 is able to determine the junction temperature of each LED 93-98, as in block 117.

Microprocessor 60 then modifies the current supplied to each LED, if necessary or desired, as in block 118. For example, microprocessor 60 can modify the pulse-width modulation of the power provided to current sources 70-75 by modulator 65, or it can individually control any one or more of the current sources 70-75 to achieve the desired current level.

Lastly, microprocessor 60 can test any of the LEDs 93-98 by changing the current levels for short periods of time to test each LED for conformance to the typical diode voltage-current characteristic, as in block 119. This is accomplished by reducing the current through each LED, preferably in some sequential order, by controlling one of the current sources 70-75. The selected current source is then controlled to various low levels of current and the resultant voltages are measured by the A/D converters 77-79. These various current levels are selected across the non-linear portion of the diode characteristic curve and are compared against a correct version of the curves stored in the memory of microprocessor 60. This test is done very quickly for each LED so that the overall illumination of the LED signal is not perceptible to the human eye.

The above described measurements and tests may be repeated as frequently as desired. For example, the tests may be performed once each second.

The foregoing tests accurately measure the current through each LED. The pulse-width modulation of the current supplied to the LEDs ensures that the proper average current is individually sourced to each LED. The average current to the LEDs is also modified in accordance with the junction temperature of each LED, as determined by microprocessor 60 from data supplied by A/D converters 77-79. Since LED brilliance varies in accordance with ambient temperature, the foregoing techniques also control the LEDs to provide uniform light output irrespective of the ambient temperature. A separate temperature sensor is not needed since the microprocessor 60 determines the junction temperature of each LED based upon the linear dependence of the forward biased junction potential of the LED with temperature. Microprocessor 60 compares the known junction potential at a reference temperature, such as 20° C., and determines the current junction temperature by the difference of the junction potential from that at the reference temperature.

While particular embodiments of the invention have been shown and described, it will be obvious to those skilled in the art that changes and modifications may be made therein without departing from the invention in its broader aspects.

1. A system for controlling power to light emitting diodes in signaling apparatus, said system comprising:
a plurality of light emitting diodes;
a plurality of current sources for supplying current to each of said light emitting diodes with a separate current source associated with each of said plurality of light emitting diodes;
a data processor with a bus for receiving and sending data, said data processor in communication with said current sources for controlling the amount of current supplied by each current source;
a plurality of resistors in series between the plurality of current sources and the plurality of light emitting diodes; and
a first analog-to-digital converter for determining the voltage potential at each of said plurality of resistors and for providing a digital representation of each determined voltage potential to said data processor;
said data processor using the digital representations of each determined voltage potential to control the amount of current supplied by each current source to its associated light emitting diode.

2. The system as defined in accordance with claim 1 further comprising:
a second analog-to-digital converter for determining the voltage potential of each of said plurality of light emitting diodes and for providing a digital representation of the voltage potential at each light emitting diode to said data processor;
said data processor using the digital representation of the voltage potential at each light emitting diode to determine the junction temperature of each light emitting diode to control the amount of current supplied by each current source to its associated light emitting diode to control the junction temperature thereof.

3. The system as defined in accordance with claim 2 wherein said data processor determines the junction temperature of each light emitting diode by determining the difference between the actual forward bias voltage and the normal forward bias voltage at a known temperature and by applying a coefficient of temperature related to the forward bias voltage of the light emitting diodes to said difference in forward bias voltages.

4. The system as defined in accordance with claim 1 further comprising:
a pulse-width modulator coupled to a source of power and to said plurality of current sources, said pulse-width modulator in communication with said data processor to control the amount of power supplied to the plurality of current sources.

5. The system as defined in accordance with claim 1 further comprising:
an energy storage and limiter circuit for receiving and storing input power and for supplying power to said data processor in the absence of normal input power.

6. The system as defined in accordance with claim 1 further comprising:
a vital disconnect for disconnecting the system from the source to emulate an open circuit.

7. The system as defined in accordance with claim 1 further comprising:
a vital load circuit to emulate the load drawn by an incandescent lamp.

8. The system as defined in accordance with claim 7 wherein the vital load circuit draws sufficient current to satisfy hot filament tests.

9. The system as defined in accordance with claim 1 wherein said data processor controls said plurality of current sources to provide a plurality of different current levels to each light emitting diode and said data processor compares the digital representations of the voltage received from said second analog-to-digital converter corresponding to each of said plurality of different current levels to a diode voltage-current characteristic stored in memory of the data processor.

10. The system as defined in accordance with claim 9 wherein said data processor sequentially tests each light emitting diode by sequentially controlling the plurality of current sources to provide the plurality of different current levels to each light emitting diode.

11. The system as defined in accordance with claim 9 wherein the testing of each light emitting diode is performed sufficiently rapidly to avoid the human perception of a loss of illumination from the light emitting diodes.

12. The system as defined in accordance with claim 9 wherein said data processor causes the system to be vitally disconnected from the source if it is determined that a predetermined number of light emitting diodes do not pass the test of comparing the voltages at the light emitting diodes to the stored diode voltage-current characteristic.

13. A method for controlling power to light emitting diodes in signaling apparatus, said signaling apparatus including a plurality of light emitting diodes, a plurality of current sources, a separate current source associated with each of said plurality of light emitting diodes, a plurality of resistors in series between the plurality of current sources and the plurality of light emitting diodes, said method comprising the steps of:
supplying current to the plurality of light emitting diodes with the plurality of current sources;
controlling the amount of current supplied to each light emitting diode by each current source;
determining the voltage potential at each of said resistors;
providing a digital representation of the voltage potential at each of said resistors; and
using the digital representations of each determined voltage potential to control the amount of current supplied by each current source to its associated light emitting diode.

14. The method as defined in accordance with claim 13 further comprising the steps of:
determining the voltage potential of each of said plurality of light emitting diodes;
providing a digital representation of the voltage potential at each light emitting diode;
using the digital representation of the voltage potential at each light emitting diode to determine the junction temperature of each light emitting diode; and
controlling the amount of current supplied by each current source to its associated light emitting diode based upon the determined junction temperature.

15. The method as defined in accordance with claim 14 further comprising the steps of:
determining the difference between the actual forward bias voltage and the normal forward bias voltage at a known temperature for each light emitting diode; and
applying a coefficient of temperature related to the forward bias voltage of the light emitting diodes to said difference in forward bias voltages to determine the junction temperature of each light emitting diode.

16. The method as defined in accordance with claim 13 further comprising the step of:
pulse-width modulating the power supplied to said plurality of current sources to control the amount of current supplied by the plurality of current sources to the plurality of light emitting diodes.

17. The method as defined in accordance with claim 13 further comprising the step of:
receiving and storing input power for said data processor; and
supplying power to said data processor from the stored input power in the absence of normal input power.

18. The method as defined in accordance with claim 13 further comprising the step of:
vitally disconnecting the signaling apparatus from the source to emulate an open circuit.

19. The method as defined in accordance with claim 13 further comprising the step of:
using a vital load circuit to emulate the load drawn by an incandescent lamp.

20. The method as defined in accordance with claim 19 further comprising the step of:
using the vital load circuit to draw sufficient current to satisfy hot filament tests.

21. The method as defined in accordance with claim 13 further comprising the steps of:
controlling said plurality of current sources to provide a plurality of different current levels to each light emitting diode; and
comparing the digital representations of the voltage corresponding to each of said plurality of different current levels to a stored diode voltage-current characteristic.

22. The method as defined in accordance with claim 21 further comprising the step of:
sequentially testing each light emitting diode by sequentially controlling the plurality of current sources to provide the plurality of different current levels to each light emitting diode.

23. The method as defined in accordance with claim 21 further comprising the step of:
testing each light emitting diode sufficiently rapidly to avoid the human perception of a loss of illumination from the light emitting diodes.

24. The method as defined in accordance with claim 21 further comprising the step of:
vitally disconnecting the signaling apparatus from the source if it is determined that a predetermined number of light emitting diodes do not pass the test of comparing the voltages at the light emitting diodes to the stored diode voltage-current characteristic.
